(19) United States
(12) Patent Application Publication
(10) Pub. No.: US 2026/0223279 A1
(43) Pub. Date: Jul. 30, 2026

(54) PRINTED CIRCUIT BOARD (PCB) MINIATURIZATION BY AN EMBEDDED VIA-IN-VIA DESIGN

(71) Applicant: GOOGLE LLC, Mountain View, CA (US)

(72) Inventors: Yu-Ting CHUNG, Mountain View, CA (US); Yu-Hao HSU, New Taipei City (TW); Ta Yu LAI, New Taipei City (TW); Shang-Jing WU, New Taipei City (TW); Chee Koang CHEN, New Taipei City (TW)

(73) Assignee: GOOGLE LLC, Mountain View, CA (US)

(21) Appl. No.: 19/140,184

(22) PCT Filed: Jan. 30, 2023
(86) PCT No.: PCT/CN2023/073776

§ 371 Date: Jun. 17, 2025

(51) Int. Cl. H05K 1/02; H05K 1/03; H05K 1/11; H05K 3/00; H05K 3/46

(52) U.S. Cl. CPC H05K 1/0222; H05K 1/03; H05K 1/116; H05K 3/0026; H05K 3/4644; H05K 2201/093; H05K 2201/09536; H05K 2201/096; H05K 2201/09609; H05K 2201/09618

(57) ABSTRACT

A multi-layer printed circuit board (PCB) and a method of manufacturing thereof are provided. The PCB includes a core layer, a first stack of alternative layers including metal layers and dielectric layers stacked alternatively over a top surface of the core layer, a second stack of alternative layers including metal layers and dielectric layers stacked alternatively over a bottom surface of the core layer, and an embedded via structure through the core layer and connecting a first metal layer of the first stack of alternative layers to a second metal layer of the second stack of alternative layers. The embedded via structure includes a first signal path layer through the core layer, a first ground layer through the core layer and enclosing the first signal path layer, and a first dielectric layer through the core layer and between the first signal path layer and the first ground layer.

### TECHNICAL FIELD

The present disclosure relates to a size miniaturization in printed circuit board.

### BACKGROUND

A form-factor reduction of a printed circuit board (PCB) can provide a smaller and a lighter product given the same product performance, or provide a better product performance given the same product size. For example, the form-factor reduction can improve PCB design flexibility, leading to product design flexibility (e.g. improved battery capacity of a smartphone).

### SUMMARY

Aspects of the disclosure provide a multi-layer printed circuit board (PCB). The PCB includes a core layer, a first stack of alternative layers including metal layers and dielectric layers stacked alternatively over a top surface of the core layer, a second stack of alternative layers including metal layers and dielectric layers stacked alternatively over a bottom surface of the core layer, and an embedded via structure through the core layer and connecting a first metal layer of the first stack of alternative layers to a second metal layer of the second stack of alternative layers. The embedded via structure includes a first signal path layer through the core layer, a first ground layer through the core layer and enclosing the first signal path layer, and a first dielectric layer through the core layer and between the first signal path layer and the first ground layer.

In an embodiment, the embedded via structure further includes a second dielectric layer that is enclosed by the first signal path layer.

In an embodiment, the embedded via structure further includes a second signal path layer that is enclosed by the first ground layer.

In an embodiment, the first and second signal path layers are not enclosed by each other.

In an embodiment, one of the first and second signal path layers is enclosed by the other of the first and second signal path layers.

In an embodiment, the embedded via structure further includes a third dielectric layer that is enclosed by the second signal path layer.

In an embodiment, the embedded via structure further includes a second ground layer enclosed by the first signal path layer.

In an embodiment, the embedded via structure further includes a fourth dielectric layer enclosed by the second ground layer.

In an embodiment, the core layer and the dielectric layers include a prepreg dielectric material.

In an embodiment, the core layer has a cavity.

Aspects of the disclosure further provide a method of manufacturing a PCB. The method includes, forming a first stack of alternative layers including metal layers and dielectric layers stacked alternatively over a top surface of a core layer of the PCB, forming a second stack of alternative layers including metal layers and dielectric layers stacked alternatively over a bottom surface of the core layer, and forming an embedded via structure through the core layer and connecting a first metal layer of the first stack of alternative layers to a second metal layer of the second stack of alternative layers. The embedded via structure includes a first signal path layer through the core layer, a first ground layer through the core layer and enclosing the first signal path layer, and a first dielectric layer through the core layer and between the first signal path layer and the first ground layer.

In an embodiment, the embedded via structure further includes a second dielectric layer that is enclosed by the first signal path layer.

In an embodiment, the embedded via structure further includes a second signal path layer that is enclosed by the first ground layer.

In an embodiment, the first and second signal path layers are not enclosed by each other.

In an embodiment, one of the first and second signal path layers is enclosed by the other of the first and second signal path layers.

In an embodiment, the embedded via structure further includes a third dielectric layer that is enclosed by the second signal path layer.

In an embodiment, the embedded via structure further includes a second ground layer enclosed by the first signal path layer.

In an embodiment, the embedded via structure further includes a fourth dielectric layer enclosed by the second ground layer.

In an embodiment, the core layer and the dielectric layers include a prepreg dielectric material.

In an embodiment, the core layer has a cavity.

Aspects of the disclosure further provide a non-transitory computer-readable storage medium including computer executable instructions, wherein the instructions, when executed by a computer, cause the computer to perform a method, the method comprising: forming a first stack of alternative layers including metal layers and dielectric layers that are stacked alternatively over a top surface of a core layer of the PCB; forming a second stack of alternative layers including metal layers and dielectric layers that are stacked alternatively over a bottom surface of the core layer; and forming an embedded via structure that is through the core layer and connects a first metal layer of the first stack of alternative layers to a second metal layer of the second stack of alternative layers, the embedded via structure including a first signal path layer that is through the core layer, a first ground layer that is through the core layer and encloses the first signal path layer, and a first dielectric layer that is through the core layer and between the first signal path layer and the first ground layer.

### BRIEF DESCRIPTION OF THE DRAWINGS

Various embodiments of this disclosure that are proposed as examples will be described in detail with reference to the following figures, wherein like numerals reference like elements, and wherein:

FIG. 1A an exemplary cross section of a multi-layer PCB 100 according to embodiments of the disclosure;

FIG. 1B shows an exemplary via pattern of the multi-layer PCB 100 according to embodiments of the disclosure;

FIG. 2A shows an exemplary cross-section of a multi-layer PCB 200 according to embodiments of the disclosure;

FIG. 2B shows an exemplary via pattern 230 of the multi-layer PCB 200 according to embodiments of the disclosure;

FIG. 3A shows an exemplary cross-section of a multi-layer PCB 300 according to embodiments of the disclosure;

FIG. 3B shows an exemplary via pattern of an embedded via structure 310 in the multi-layer PCB 300 according to embodiments of the disclosure;

FIG. 3C shows an exemplary cross-section of a multi-layer PCB 320 according to embodiments of the disclosure;

FIG. 3D shows an exemplary via pattern of an embedded via structure 330 in the multi-layer PCB 320 according to embodiments of the disclosure;

FIG. 3E shows an exemplary cross-section of a multi-layer PCB 340 according to embodiments of the disclosure;

FIG. 3F shows an exemplary via pattern of an embedded via structure 350 in the multi-layer PCB 340 according to embodiments of the disclosure;

FIG. 3G shows an exemplary cross-section of a multi-layer PCB 360 according to embodiments of the disclosure;

FIG. 3H shows an exemplary via pattern of an embedded via structure 370 in the multi-layer PCB 360 according to embodiments of the disclosure;

FIG. 4A shows an exemplary via pattern 400 using a non-eViV structure according to embodiments of the disclosure;

FIG. 4B shows an exemplary via pattern 420 using an eViV structure according to embodiments of the disclosure;

FIG. 4C shows an insertion loss comparison 430 between the non-eViV structure 400 and the eViV structure 420;

FIG. 4D shows a far-end crosstalk comparison 440 between the non-eViV structure 400 and the eViV structure 420;

FIG. 4E shows an insertion loss comparison 450 between the non-eViV structure 400 and the eViV structure 420;

FIG. 4F shows a far-end crosstalk comparison 460 between the non-eViV structure 400 and the eViV structure 420; and

FIG. 5 is a schematic of a hardware configuration of a device according to embodiments of the present disclosure.

### DETAILED DESCRIPTION OF EMBODIMENTS

Printed circuit board (PCB) miniaturization can provide various benefits to an electronic device. The PCB miniaturization can result in a substantial reduction in an overall weight and a packaged size with an improvement in performance for the electronic device, especially when the electronic device is a consumer device or a wearable device (e.g., a computer, a tablet, a smartphone, a smart watch, a digital camera, and the like) that has a limited PCB space. Accordingly, high density interconnect (HDI) is usually implemented in such an electronic device for the PCB miniaturization.

The HDI can increase functionality of the PCB within a same or reduced area, by taking advantage of the trend in miniaturization of semiconductor and other component packages. For example, the HDI can allow a larger number of active components in the electronic device, leading a more powerful and more compact device in a same space of the product with an enhanced performance.

Further, the HDI can result in resistance and capacitance reduction for passive components in the electronic device since a travel distance of a signal becomes shorter in the high-density design. The reduction in circuit resistance, capacitance, and inductance can allow circuits to work with a lower voltage and current, so that a smaller battery can be applicable for the electronic device. As heat generated by the components of the electronic device can be reduced with the PCB miniaturization, the electronic device may not require a large heat sink or a cooling fan to keep temperatures in check.

In addition, the PCB miniaturization can improve signal integrity within the PCB, leading to not only a better performance of the electronic device, but also a replacement of a current design with a faster circuit with improved functionality.

This disclosure provides methods and embodiments for the PCB miniaturization.

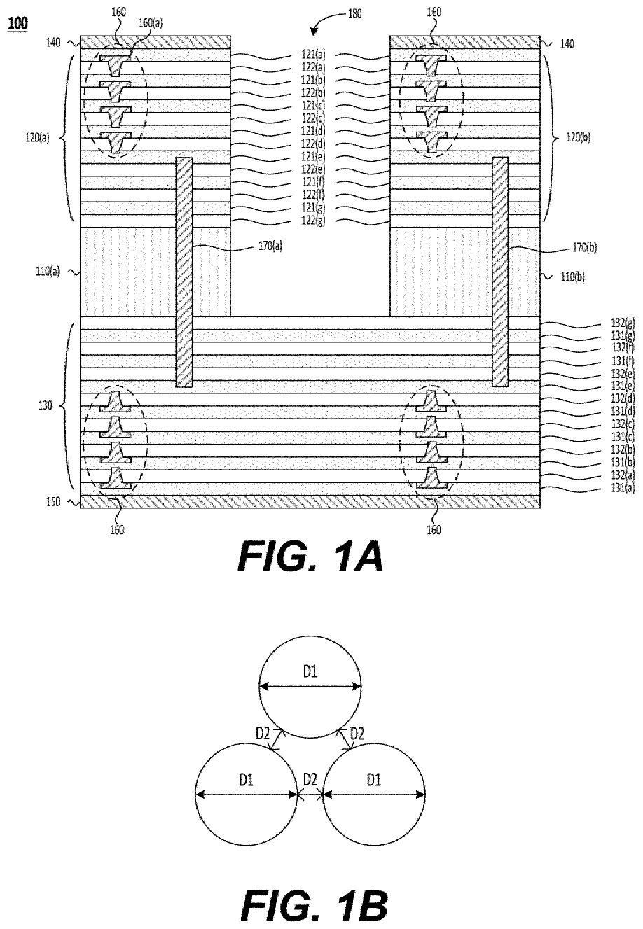

FIG. 1A shows an exemplary cross section of a multi-layer PCB 100 according to embodiments of the disclosure.

In the example of FIG. 1A, the multi-layer PCB 100 includes a core layer 110, a first stack of alternative layers 120, and a second stack of alternative layers 130. The first stack of alternative layers 120 includes metal layers 121(a)-(g) and dielectric layers 122(a)-(g) that are stacked alternatively over a top surface of the core layer 110. The second stack of alternative layers 130 includes metal layers 131(a)-(g) and dielectric layers 132(a)-(g) that are stacked alternatively over a bottom surface of the core layer 110.

It is noted that a number of the alternative layers in each stack is not limited in this disclosure. In an example, there can be a single metal layer and/or a single dielectric layer in one or both stacks.

In the example of FIG. 1A, the multi-layer PCB 100 has a cavity 180 which separates the first stack of alternative layers 120 into two sub-stacks 120(a) and 120(b) and separates the core layer 110 into two sub-layers 110(a) and 110(b).

It is noted that a depth of the cavity 180 is not limited in this disclosure. In an example, the PCB 100 may not have a cavity, or the cavity may separate only a portion of the first stack of alternative layers without separating the core layer, or the cavity may separate the first stack of the alternative layers and only a portion of the core layer, or the cavity may separate the first stack of alternative layers, the core layer, and only a portion of the second stack of alternative layers.

In the example of FIG. 1A, the multi-layer PCB 100 includes a first solder mask (SM) layer 140 on a top surface of the metal layer 121(a) and a second SM layer 150 on a top surface of the metal layer 131(a).

It is noted that there may not be the first SM layer 140 and/or the second SM layer 150 in an example.

In the example of FIG. 1A, the multi-layer PCB 100 includes a first plurality of vias 160 and a second plurality of vias 170.

Each of the first plurality of vias 160 can electrically connect one metal layer to an adjacent metal layer. For example, the via 160(a) can electrically connect the metal layer 121(a) to the metal layer 121(b). The first plurality of vias 160 can be laser-drilled vias for example.

Each of the second plurality of vias 170 can electrically connect a first metal layer in the first stack of alternative layers 120 to a second metal layer in the second stack of alternative layers 130 through the core layer 110. For example, the via 170(a) can electrically connect the metal layer 121(e) in the first stack of alternative layers 120 to the metal layer 131(e) in the second stack of alternative layers 130 through the core layer 110. The second plurality of vias 170 can be buried vias or plated through hole (PTH) vias for example.

It is noted that a number of the first plurality of vias 160 and/or a number of the second plurality of vias 170 are not limited in this disclosure. In an example, there can be a single first via and/or a single second via.

FIG. 1B shows an exemplary via pattern of the multi-layer PCB 100 according to embodiments of the disclosure. A via diameter and a via-to-via gap can be represented by D1 and D2, respectively. In an example, a minimum diameter achievable for a buried via can be 450 μm and a minimum via-to-via gap can be 70 μm. It can be seen from FIG. 1B, the smaller the via diameter and the via-to-via gap, the via pattern with a higher density can be obtained.

However, the minimum via diameter and/or the minimum via-to-via gap are dependent on a process capability of a PCB manufacturer and thus can be limited.

One challenge for miniaturization of the via diameter and via-to-via gap is signal integrity of a high-speed signal that travels through the via. The high-speed signal can be for example a RF signal or a high speed differential pair signal such as USB signal, PCIE signal, MIPI signal, and the like. If there is no reference ground for these high-speed signals, it is easy to have a cross-talk effect and to cause poor signal integrity. Thus, a reference ground (GND) can be added around the signal to protect the high-speed signal. For RF signal, a circle of GND around the RF signal can be added to improve the signal integrity. For a high speed differential pair signal such as USB, PCIE, or MIPI, a circle of GND can be added around the high speed differential pair signal to improve the signal integrity.

In addition, with the cavity PCB architecture, another challenge is how to optimize the placement with a limited PCB space to have enough signal routing traces. The signal traces reply on laser vias and buried vias (or PTH vias) to be connected in different metal layers. The signal traces passing through the PCB core layer can be usually achieved through buried or PTH vias, as shown in FIG. 1A.

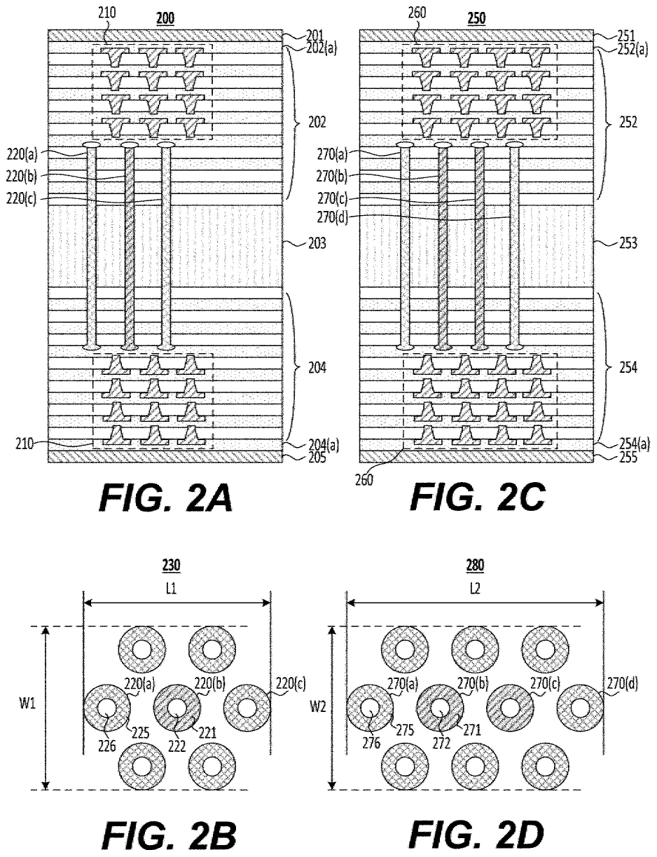

FIG. 2A shows an exemplary cross-section of a multi-layer PCB 200 according to embodiments of the disclosure. Similar to the multi-layer PCB 100 in FIG. 1A, the multi-layer PCB 200 includes a core layer 203, a first stack of alternative layers 202 including metal layers and dielectric layers that are alternatively stacked on a top surface of the core layer 203, a first SM layer 201 on a top surface of a first metal layer 202(a) in the first stack of the alternative layers 202, a second stack of alternative layers 204 including metal layers and dielectric layers that are alternatively stacked on a bottom surface of the core layer 203, and a second SM layer 205 on a top surface of a second metal layer 204(a) in the second stack of the alternative layers 204.

The multi-layer PCB 200 further includes a first plurality of vias 210 and a second plurality of vias 220. Each of the first plurality of vias 210 can electrically connect one metal layer to an adjacent metal layer. The first plurality of vias 210 can be laser-drilled vias for example. Each of the second plurality of vias 220 can electrically connect a first metal layer in the first stack of alternative layers 202 to a second metal layer in the second stack of alternative layers 204 through the core layer 203. The second plurality of vias 220 can be buried vias or plated through hole (PTH) vias for example.

In the second plurality of vias 220, the via 220(b) is used for a signal such as high-speed signal, and the vias 220(a) and 220 (c) are used for reference ground GND to protect the signal and improve signal integrity of the signal.

FIG. 2B shows an exemplary via pattern 230 of the multi-layer PCB 200 according to embodiments of the disclosure. In the via pattern 230, a plurality of GND vias such as the GND vias 220(a) and 220(c) surround the signal via 220(b) to protect the signal travelling through the signal via 220(b) and improve the signal integrity of the signal. The signal via 220(b) includes a metal layer 221 and a dielectric layer 222 that is enclosed by the metal layer 221. Each GND via such as the GND via 220(a) includes a metal layer 225 and a dielectric layer 226 that is enclosed by the metal layer 225. The dielectric layers 222 and 226 can be used for isolation and supporting of the signal via 220(b) and the GND via 220(a), respectively.

FIG. 2C shows an exemplary cross-section of a multi-layer PCB 250 according to embodiments of the disclosure. Similar to the multi-layer PCB 100 in FIG. 1A and the multi-layer PCB 200 in FIG. 2A, the multi-layer PCB 200 includes a core layer 253, a first stack of alternative layers 252 including metal layers and dielectric layers that are alternatively stacked on a top surface of the core layer 253, a first SM layer 251 on a top surface of a first metal layer 252(a) in the first stack of the alternative layers 252, a second stack of alternative layers 254 including metal layers and dielectric layers that are alternatively stacked on a bottom surface of the core layer 253, and a second SM layer 255 on a top surface of a second metal layer 254(a) in the second stack of the alternative layers 254.

The multi-layer PCB 250 further includes a first plurality of vias 260 and a second plurality of vias 270. Each of the first plurality of vias 260 can electrically connect one metal layer to an adjacent metal layer. The first plurality of vias 260 can be laser-drilled vias for example. Each of the second plurality of vias 270 can electrically connect a first metal layer in the first stack of alternative layers 252 to a second metal layer in the second stack of alternative layers 254 through the core layer 253. The second plurality of vias 270 can be buried vias or plated through hole (PTH) vias for example.

In the second plurality of vias 270, the vias 270(b) and 270(c) are used for a differential pair signal such as high-speed differential pair signal, and the vias 270(a) and 270 (d) are used for reference ground GND to protect the differential pair signal and to improve signal integrity of the differential pair signal.

FIG. 2D shows an exemplary via pattern 280 of the multi-layer PCB 250 according to embodiments of the disclosure. In the via pattern 280, a plurality of GND vias such as the GND vias 270(a) and 270(d) surround the signal vias 270(b) and 270(c) to protect the differential pair signal travelling through the signal vias 270(b) and 270(c) and to improve the signal integrity of the differential pair signal. Each signal via such as the signal via 270(b) includes a metal layer 271 and a dielectric layer 272 that is enclosed by the metal layer 271.

Each GND via such as the GND via 270(a) includes a metal layer 275 and a dielectric layer 276 that is enclosed by the metal layer 275. The dielectric layers 272 and 276 can be used for isolation and supporting of the signal via 270(b) and the GND via 270(a), respectively.

To further achieve a PCB miniaturization, this disclosure provides an embedded-Via-in-Via (eViV) structure, i.e., an inner via is embedded or covered by an outer via. With the eViV structure, a reduced PCB area (PCB miniaturization with lighter in weight) and improved signal integrity can be achieved, leading to a more flexible product design (e.g. an improved battery capacity for the product). In other words, give a same PCB area, a higher density pattern can be achieved.

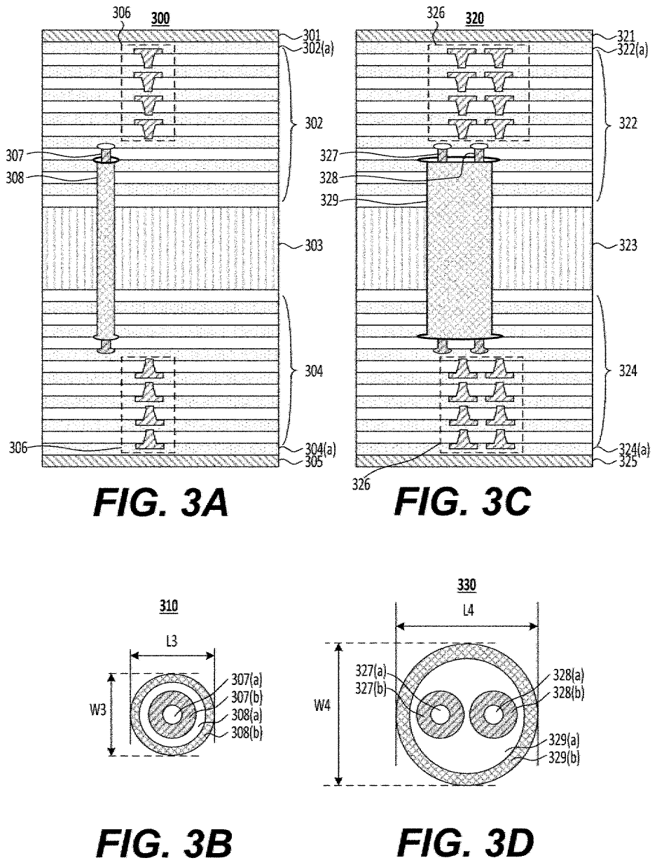

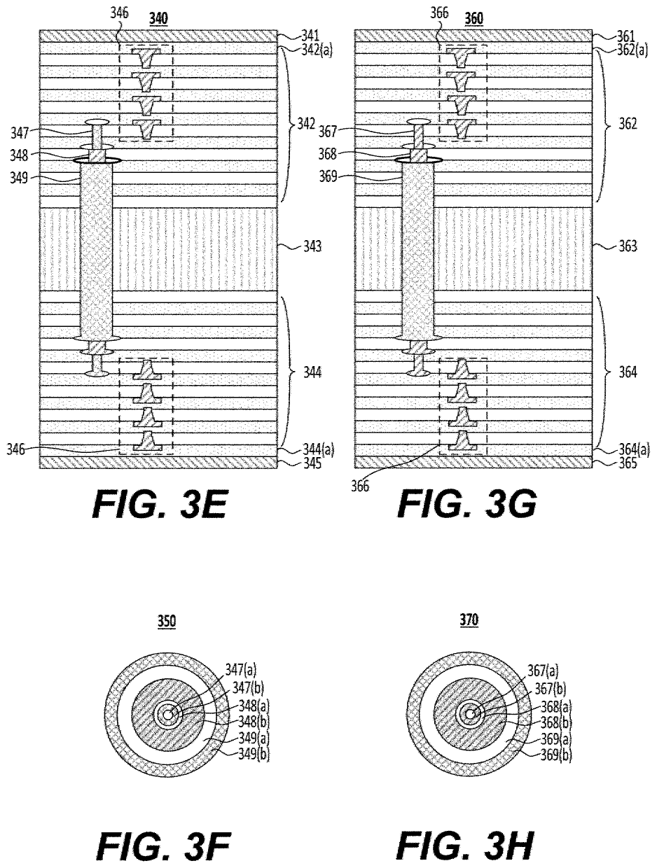

Details of the eViV structure will be described with referencing to examples in FIGS. 3A-3H.

FIG. 3A shows an exemplary cross-section of a multi-layer PCB 300 according to embodiments of the disclosure. The multi-layer PCB 300 includes a core layer 303, a first stack of alternative layers 302 including metal layers and dielectric layers that are alternatively stacked on a top surface of the core layer 303, a first SM layer 301 on a top surface of a first metal layer 302(a) in the first stack of the alternative layers 302, a second stack of alternative layers 304 including metal layers and dielectric layers that are alternatively stacked on a bottom surface of the core layer 303, and a second SM layer 305 on a top surface of a second metal layer 304(a) in the second stack of the alternative layers 304.

The multi-layer PCB 300 further includes a first plurality of vias 306 and a second plurality of vias 307 and 308. Each of the first plurality of vias 306 can electrically connect one metal layer to an adjacent metal layer. The first plurality of vias 306 can be laser-drilled vias for example. Each of the second plurality of vias 307 and 308 can electrically connect a first metal layer in the first stack of alternative layers 302 to a second metal layer in the second stack of alternative layers 304 through the core layer 303. The second plurality of vias 307 and 308 can be buried vias or plated through hole (PTH) vias for example.

In the second plurality of vias 307 and 308, the via 307 can be used for a signal such as a high-speed signal, and the via 308 can be used for reference ground GND to protect the signal and improve signal integrity of the signal. The signal via 307 is enclosed by the GND via 308 along the cross-section and through the core layer 303. The signal via 307 and the GND via 308 can form an embedded via structure 310 of the eViV structure.

FIG. 3B shows an exemplary via pattern of the embedded via structure 310 in the multi-layer PCB 300 according to embodiments of the disclosure. The embedded via structure 310 includes a first dielectric layer 307(a), a first metal layer 307(b), a second dielectric layer 308(a), and a second metal layer 308(b). The first metal layer 307(b) and the second metal layer 308(b) are a signal path layer and a GND layer, respectively. The signal path layer 307(b) is enclosed by the GND layer 308(b). The first dielectric layer 307(a) is enclosed by the signal path layer 307(b), and the second dielectric layer 308(a) is disposed between the signal path layer 307(b) and the GND layer 308(b). The first dielectric layer 307(a) and the second dielectric layer 308(a) can be used for isolation and supporting of the signal via 307 and the GND via 308, respectively.

It is noted that a size of the embedded via structure 310 (e.g., W3×L3) is smaller than a size of the via pattern 230 (e.g., W1×L1), and dimensions of the embedded via structure 310 are also less than dimensions of the via pattern 230 (e.g., L3<L1, W3<W1). Accordingly, the multi-layer PCB 300 can have a higher density than the PCB 200.

FIG. 3C shows an exemplary cross-section of a multi-layer PCB 320 according to embodiments of the disclosure. The multi-layer PCB 320 includes a core layer 323, a first stack of alternative layers 322 including metal layers and dielectric layers that are alternatively stacked on a top surface of the core layer 323, a first SM layer 321 on a top surface of a first metal layer 322(a) in the first stack of the alternative layers 322, a second stack of alternative layers 324 including metal layers and dielectric layers that are alternatively stacked on a bottom surface of the core layer 323, and a second SM layer 325 on a top surface of a second metal layer 324(a) in the second stack of the alternative layers 324.

The multi-layer PCB 320 further includes a first plurality of vias 326 and a second plurality of vias 327-329. Each of the first plurality of vias 326 can electrically connect one metal layer to an adjacent metal layer. The first plurality of vias 326 can be laser-drilled vias for example. Each of the second plurality of vias 327-329 can electrically connect a first metal layer in the first stack of alternative layers 322 to a second metal layer in the second stack of alternative layers 324 through the core layer 323. The second plurality of vias 327-329 can be buried vias or plated through hole (PTH) vias for example.

In the second plurality of vias 327-329, the vias 327-328 can be used for a differential pair signal such as high-speed differential pair signal, and the via 329 can be used for reference ground GND to protect the signal and improve signal integrity of the signal. The signal vias 327-328 are enclosed by the GND via 329 along the cross-section and through the core layer 323. The signal vias 327-328 and the GND via 329 can form an embedded via structure 330 of the eViV structure.

FIG. 3D shows an exemplary via pattern of the embedded via structure 330 in the multi-layer PCB 320 according to embodiments of the disclosure. The embedded via structure 330 includes a first dielectric layer 327(a), a first metal layer 327(b), a second dielectric layer 328(a), a second metal layer 328(b), a third dielectric layer 329(a), and a third metal layer 329(b). The first metal layer 327(b) and the second metal layer 328(b) are signal path layers, and the third metal layer 329(b) is the GND layer. The signal path layers 327(b) and 328(b) are separated by an allowed via-to-via gap (e.g., a minimum via-to-via gap) and are enclosed by the GND layer 329(b). The first dielectric layer 327(a) and the second dielectric layer 328(a) are enclosed by the signal path layers 327(b) and 328(b), respectively. The third dielectric layer 329(a) is disposed inside the GND layer 329(b) and outside the signal path layers 327(b) and 328(b). The first dielectric layer 327(a), the second dielectric layer 328(a), and the third dielectric layer 329(a) can be used for isolation and supporting of the signal via 327, the signal via 328, and the GND via 329, respectively.

It is noted that a size of the embedded via structure 330 (e.g., W4×L4) is smaller than a size of the via pattern 280 (e.g., W2×L2), and dimensions of the embedded via structure 330 are also less than dimensions of the via pattern 280 (e.g., W4<W2, L4<L2). Accordingly, the multi-layer PCB 320 can have a higher density than the PCB 250.

FIG. 3E shows an exemplary cross-section of a multi-layer PCB 340 according to embodiments of the disclosure. The multi-layer PCB 340 includes a core layer 343, a first stack of alternative layers 342 including metal layers and dielectric layers that are alternatively stacked on a top surface of the core layer 343, a first SM layer 341 on a top surface of a first metal layer 342(a) in the first stack of the alternative layers 342, a second stack of alternative layers 344 including metal layers and dielectric layers that are alternatively stacked on a bottom surface of the core layer 343, and a second SM layer 345 on a top surface of a second metal layer 344(a) in the second stack of the alternative layers 344.

The multi-layer PCB 340 further includes a first plurality of vias 346 and a second plurality of vias 347-349. Each of the first plurality of vias 346 can electrically connect one metal layer to an adjacent metal layer. The first plurality of vias 346 can be laser-drilled vias for example. Each of the second plurality of vias 347-349 can electrically connect a first metal layer in the first stack of alternative layers 342 to a second metal layer in the second stack of alternative layers 344 through the core layer 343. The second plurality of vias 347-349 can be buried vias or plated through hole (PTH) vias for example.

In the second plurality of vias 347-349, the via 348 can be used for a signal such as a high-speed signal, and the vias 347 and 349 can be used for reference ground GND to protect the signal and improve signal integrity of the signal. The GND via 347 is enclosed by the signal via 348 along the cross-section and through the core layer 343. The signal via 348 is enclosed by the GND via 349 along the cross-section and through the core layer 343. The signal via 348 and the GND vias 347 and 349 can form an embedded via structure 350 (i.e., GND-signal-GND structure) of the eViV structure.

FIG. 3F shows an exemplary via pattern of the embedded via structure 350 in the multi-layer PCB 340 according to embodiments of the disclosure. The embedded via structure 350 includes a first dielectric layer 347(a), a first metal layer 347(b), a second dielectric layer 348(a), a second metal layer 348(b), a third dielectric layer 349(a), and a third metal layer 349(b). The first metal layer 347(b) and the third metal layer 349(b) are GND layers, and the second metal layer 348(b) is a signal path layer. The GND layer 347(b) is enclosed by the signal path layer 348(b). The signal path layer 348(b) is enclosed by the GND layer 349(b). The first dielectric layer 347(a) is enclosed by the GND layer 347(b). The second dielectric layer 348(a) is disposed between the GND layer 347(b) and the signal path layer 348(b). The third dielectric layer 349(a) is disposed between the signal path layer 348(b) and the GND layer 349(b). The dielectric layers 347(a), 348(a), and 349(a) can be used for isolation and supporting of the GND via 347, the signal via 348, and the GND via 349, respectively.

FIG. 3G shows an exemplary cross-section of a multi-layer PCB 360 according to embodiments of the disclosure. The multi-layer PCB 360 includes a core layer 363, a first stack of alternative layers 362 including metal layers and dielectric layers that are alternatively stacked on a top surface of the core layer 363, a first SM layer 361 on a top surface of a first metal layer 362(a) in the first stack of the alternative layers 362, a second stack of alternative layers 364 including metal layers and dielectric layers that are alternatively stacked on a bottom surface of the core layer 363, and a second SM layer 365 on a top surface of a second metal layer 364(a) in the second stack of the alternative layers 364.

The multi-layer PCB 360 further includes a first plurality of vias 366 and a second plurality of vias 367-369. Each of the first plurality of vias 366 can electrically connect one metal layer to an adjacent metal layer. The first plurality of vias 366 can be laser-drilled vias for example. Each of the second plurality of vias 367-369 can electrically connect a first metal layer in the first stack of alternative layers 362 to a second metal layer in the second stack of alternative layers 364 through the core layer 363. The second plurality of vias 367-369 can be buried vias or plated through hole (PTH) vias for example.

In the second plurality of vias 367-369, the vias 367-368 can be used for a differential pair signal such as a high-speed differential pair signal, and the via 369 can be used for reference ground GND to protect the differential pair signal and improve signal integrity of the differential pair signal. The signal via 367 is enclosed by the signal via 368 along the cross-section and through the core layer 363. The signal via 368 is enclosed by the GND via 369 along the cross-section and through the core layer 363. The signal vias 367-368 and the GND via 369 can form an embedded via structure 370 (i.e., GND-differential signal structure) of the eViV structure.

FIG. 3H shows an exemplary via pattern of the embedded via structure 370 in the multi-layer PCB 360 according to embodiments of the disclosure. The embedded via structure 370 includes a first dielectric layer 367(a), a first metal layer 367(b), a second dielectric layer 368(a), a second metal layer 368(b), a third dielectric layer 369(a), and a third metal layer 369(b). The first metal layer 367(b) and the second metal layer 368(b) are signal path layers, and the third metal layer 369(b) is a GND layer. The signal path layer 367(b) is enclosed by the signal path layer 368(b). The signal path layer 368(b) is enclosed by the GND layer 369(b). The first dielectric layer 367(a) is enclosed by the signal path layer 367(b). The second dielectric layer 368(a) is disposed between the signal path layers 347(b) and 348(b). The third dielectric layer 369(a) is disposed between the signal path layer 368(b) and the GND layer 369(b). The dielectric layers 367(a), 368(a), and 369(a) can be used for isolation and supporting of the signal via 367, the signal via 368, and the GND via 369, respectively.

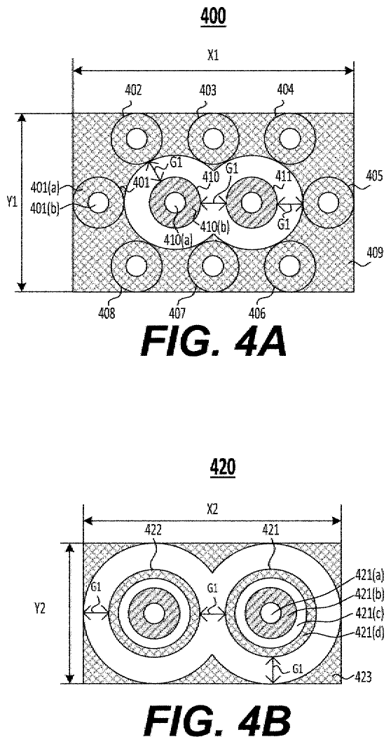

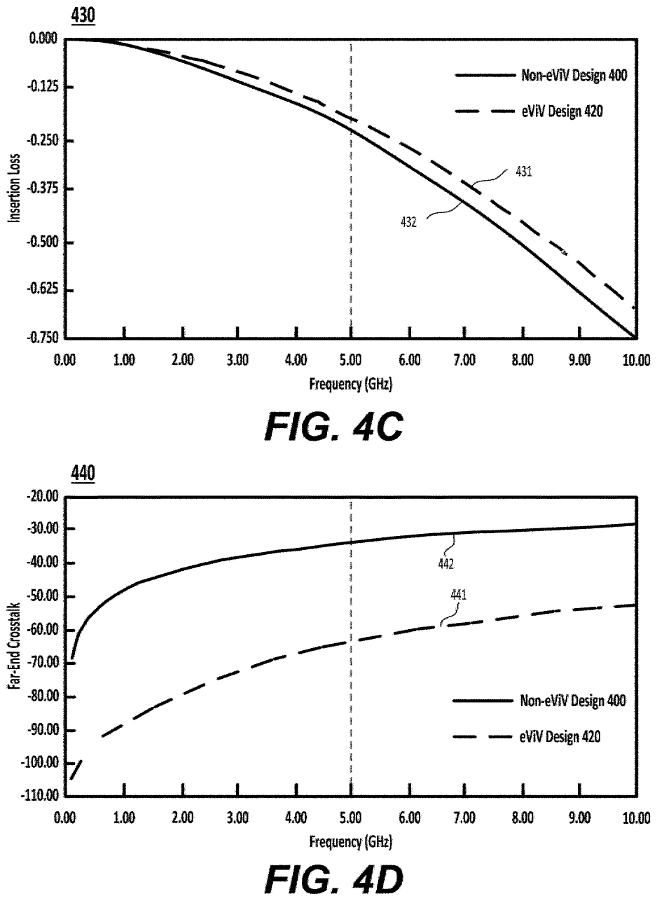

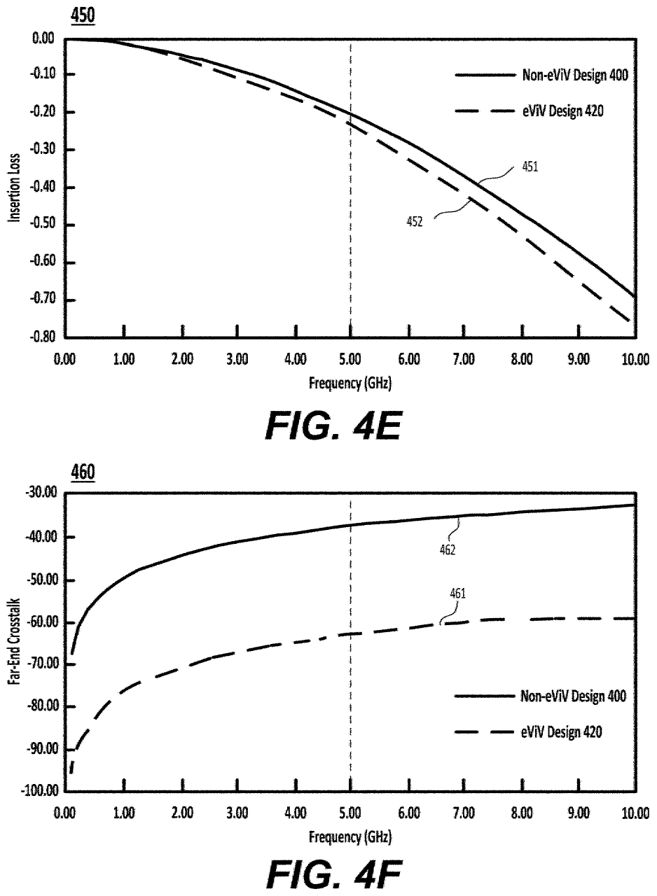

Performance improvements of a multi-layer PCB using an eViV design will be described with referencing to examples in FIGS. 4A-4F.

FIG. 4A shows an exemplary via pattern 400 using a non-eViV structure according to embodiments of the disclosure. The via pattern 400 includes a first plurality of vias 401-408 and a second plurality of vias 410-411. Each of the second plurality of vias 410-411 is used for signal transmission and each of the first plurality of vias 401-408 is used for reference ground GND of the signal transmission. Any two adjacent vias are separated by at least an allowed via-to-via gap G1 (e.g., a minimum via-to-via gap). For example, the GND via 402 and the signal via 410 are separated by the via-to-via gap G1, the GND via 405 and the signal via 411 are separated by the via-to-via gap G1, and the two signal vias 410-411 are also separated by the via-to-via gap G1. Each GND via includes a first metal layer and a first dielectric layer that is enclosed by the first metal layer. For example, the GND via 401 includes a metal layer 401(a) and a dielectric layer 401(b) that is enclosed by the metal layer 401(a). Each signal via also includes a second metal layer and a second dielectric layer that is enclosed by the second metal layer. For example, the signal via 410 includes a metal layer 410(a) and a dielectric layer 410(b) that is enclosed by the metal layer 410(a). The dielectric layers 401(b) and 410(b) can be used for isolation and supporting of the GND via 401 and the signal via 410, respectively. In addition, the via pattern 400 includes a ground plane 409.

FIG. 4B shows an exemplary via pattern 420 using an eViV structure according to embodiments of the disclosure. The via pattern 420 includes a plurality of vias 421-422. Each of the plurality of vias 421-422 includes two sub-vias in which one sub-via is used for signal transmission and the other is used for reference ground GND of the signal transmission and encloses the sub-via for the signal transmission. For example, the via 421 includes a first dielectric layer 421(a), a first metal layer 421(b), a second dielectric layer 421(c), and a second metal layer 421(d). The first dielectric layer 421(a) and the first metal layer 421(b) form the sub-via for the signal transmission, i.e., the signal sub-via; and the second dielectric layer 421(c) and the second metal layer 421(d) form the sub-via for the reference ground, i.e., the GND sub-via. The first dielectric layer 421(a) is enclosed by the first metal layer 421(b). The first metal layer 421(b) is enclosed by the second dielectric layer 421(c). The second dielectric layer 421(c) is enclosed by the second metal layer 421(d). The dielectric layers 421(a) and 421(c) can be used for isolation and supporting of the signal sub-via and the GND sub-via, respectively. The vias 421-422 are separated by at least an allowed via-to-via gap G1 (e.g., a minimum via-to-via gap). In addition, the via pattern 420 includes a ground plane 423.

In an embodiment, by using a same fabrication process structure rule, the via pattern 400 can have a length X1=2.025mm and a width Y1=1.36 mm (so that a size is 2.754 mm²), and the via pattern 420 can have a length X2=1.4mm and a width Y2=0.8 mm (so that a size is 1.120 mm²). Accordingly, a size reduction of about 60% can be achieved.

FIGS. 4C-4D show performance comparisons between the non-eViV structure 400 and the eViV structure 420 when each structure is used as a single end structure according to embodiments of the disclosure.

For the single end structure, two high-speed signals can be feed into the two signal vias of each structure, respectively. For example, a first high-speed signal can be feed into the signal via 410 of the non-eViV structure 400, a second high-speed signal can be feed into the signal via 411 of the non-eViV structure 400, and a first insertion loss and a first far-end crosstalk can be obtained by sweeping the signal frequency. For comparison, the first high-speed signal can be feed into the signal via 421 of the eViV structure and the second high-speed signal can be feed into the signal via 422 of the eViV structure. Then, a second insertion loss and a second far-end crosstalk can be obtained by sweeping the signal frequency.

Specifically, FIG. 4C shows an insertion loss comparison 430 between the non-eViV structure 400 and the eViV structure 420. In the comparison 430, traces 431-432 represent the insertion losses of the eViV structure 420 and the non-eViV structure 400, respectively. It can be seen that the insertion loss of the eViV structure 420 is better than the insertion loss of the non-eViV structure 400. For example, at the signal frequency of 5 GHz, the insertion losses of the non-eViV structure 400 and the eViV structure 420 are −0.2442 and −0.2002, respectively.

FIG. 4D shows a far-end crosstalk comparison 440 between the non-eViV structure 400 and the eViV structure 420. In the comparison 440, traces 441-442 represent the far-end crosstalk of the eViV structure 420 and the non-eViV structure 400, respectively. It can be seen that the difference of the far-end crosstalk between the non-eViV structure 400 and the eViV structure 420 is significant. For example, at the signal frequency of 5 GHz, the far-end crosstalk of the non-eViV structure 400 and the eViV structure 420 are −34.3821 and −63.6567, respectively.

Accordingly, it can be derived that, for the single end structure, the eViV structure 420 has an improved isolation performance of about 40% with a reduced PCB area of about 60%, while keeping a slightly better insertion loss when comparing to the non-eViV structure 400.

FIGS. 4E-4F show performance comparisons between the non-eViV structure 400 and the eViV structure 420 when each structure is used as a differential pair structure according to embodiments of the disclosure.

For the differential pair structure, a differential pair signal can be feed into the two signal vias of each structure, and an insertion loss and a far-end crosstalk can be obtained by sweeping the signal frequency for each structure.

Specifically, FIG. 4E shows an insertion loss comparison 450 between the non-e ViV structure 400 and the eViV structure 420. In the insertion loss comparison 450, traces 451-452 represent the insertion losses of the eViV structure 420 and the non-eViV structure 400, respectively. It can be seen that the insertion loss of the eViV structure 420 is better than the insertion loss of the non-eViV structure 400. For example, at the signal frequency of 5 GHz, the insertion losses of the non-eViV structure 400 and the eViV structure 420 are −0.2267 and −0.2481, Respectively.

FIG. 4F shows a far-end crosstalk comparison 460 between the non-eViV structure 400 and the eViV structure 420. In the comparison 460, traces 461-462 represent the far-end crosstalk of the eViV structure 420 and the non-eViV structure 400, respectively. It can be seen that the difference of the far-end crosstalk between the non-eViV structure 400 and the eViV structure 420 is significant. For example, at the signal frequency of 5 GHz, the far-end crosstalk of the non-eViV structure 400 and the eViV structure 420 are −37.2938 and −63.2440, respectively.

Accordingly, it can be derived that, for the differential pair structure, the eViV structure 420 has an improved isolation performance of about 40% with a reduced PCB area of about 60%, while keeping a similar insertion loss when comparing to the non-eViV structure 400.

It is noted that, in this disclosure, a shape of a via pattern (e.g., the via pattern 310 in FIG. 3B) of an eViV structure is not limited and can be round, oval, near rectangle, or the like. A number of signal vias (e.g., the signal via 307 in FIG. 3A or signal vias 327-328 in FIG. 3C) embedded in a GND via is not limited and can be a single one or multiple. A number of layers (e.g., a portion of the first stack of alternative layers 302, the core layer 303, and a portion of the second stack of alternative layers 304 in FIG. 3A) that the eViV structure is through in the cross-section is not limited and can be at least two.

It is also noted that a material of a dielectric layer (e.g., the dielectric layer 307(a) or 308(a) in FIG. 3B) in the eViV structure is not limited. In an example, the dielectric layer can include a prepreg material. In an example, the eViV structure may not have the dielectric layer. That is, an air gap can be used as the dielectric layer between the GND layer and the signal path layer or inside the signal path layer.

In addition, materials of a dielectric layer (e.g., the dielectric layer 302(a) in FIG. 3A) and a metal layer (e.g., the metal layer in FIG. 3A) of a multi-layer PCB are not limited. In an example, the dielectric layer can include a prepreg material. In an example, a core layer (e.g., the core layer 303 in FIG. 3A) of the multi-layer PCB and the dielectric layers above the core layer or below the core layer can include a same dielectric material. In an example, the core layer and the dielectric layers above the core layer or below the core layer can include different dielectric materials. In an example, the metal layer of the multi-layer PCB can include a copper material.

Further, a height of the dielectric layer or the metal layer of the multi-layer PCB is not limited. In an example, the height of the core layer of the multi-layer PCB can be much greater than the height of the dielectric layer or the metal layer. For example, for the multi-layer PCB 100 in FIG. 1A, the heights of the metal layers 121(a)-(g) (and the metal layers 131(a)-(g)) are 25 μm, 15 μm, 15 μm, 15 μm, 25 μm, 15 μm, and 15 μm, respectively; the heights of the dielectric layers 122(a)-(g) (and the dielectric layers 132(a)-(g)) are 45 μm, 45 μm, 45 μm, 45 μm, 45 μm, 107 μm, and 60 μm, respectively; the height of the SM layer 140 (and the SM layer 150) is 15 μm; and the height of the core layer 110 is 530 μm. Accordingly, the cavity 180 of the multi-layer PCB 100 has a depth of 1122 μm.

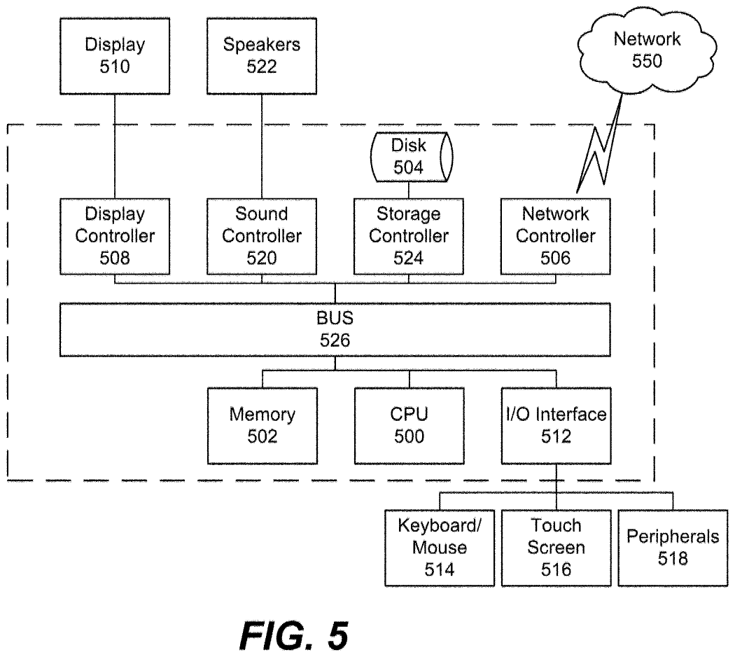

FIG. 5 shows a hardware description of a device according to embodiments of the disclosure. In FIG. 5, the device includes a CPU 500 which performs the processes described above/below, the CPU being a part of the processing circuitry. The process data and instructions may be stored in memory 502. These processes and instructions may also be stored on a storage medium disk 504 such as a hard drive (HDD) or portable storage medium or may be stored remotely. Further, the claimed advancements are not limited by the form of the computer-readable media on which the instructions of the inventive process are stored. For example, the instructions may be stored on CDs, DVDs, in FLASH memory, RAM, ROM, PROM, EPROM, EEPROM, hard disk or any other information processing device with which the device communicates, such as a server or computer.

Further, the claimed advancements may be provided as a utility application, background daemon, or component of an operating system, or combination thereof, executing in conjunction with CPU 500 and an operating system such as Microsoft Windows, UNIX, Solaris, LINUX, Apple MAC-OS and other systems known to those skilled in the art.

The hardware elements in order to achieve the device may be realized by various circuitry elements, known to those skilled in the art. For example, CPU 500 may be a Xenon or Core processor from Intel of America or an Opteron processor from AMD of America, or may be other processor types that would be recognized by one of ordinary skill in the art. Alternatively, the CPU 500 may be implemented on an FPGA, ASIC, PLD or using discrete logic circuits, as one of ordinary skill in the art would recognize. Further, CPU 500 may be implemented as multiple processors cooperatively working in parallel to perform the instructions of the processes described above.

The apparatus in FIG. 5 also includes a network controller 506, such as an Intel Ethernet PRO network interface card from Intel Corporation of America, for interfacing with network 550. As can be appreciated, the network 550 can be a public network, such as the Internet, or a private network such as an LAN or WAN network, or any combination thereof and can also include PSTN or ISDN sub-networks. The network 550 can also be wired, such as an Ethernet network, or can be wireless such as a cellular network including EDGE, 3G, 4G and 5G wireless cellular systems. The wireless network can also be Wi-Fi, Bluetooth, or any other wireless form of communication that is known.

The device further includes a display controller 508, such as a NVIDIA Geforce GTX or Quadro graphics adaptor from NVIDIA Corporation of America for interfacing with display 510, such as an LCD monitor. A general purpose I/O interface 512 interfaces with a keyboard and/or mouse 514 as well as a touch screen panel 516 on or separate from display 510. General purpose I/O interface also connects to a variety of peripherals 518 including printers and scanners.

A sound controller 520 is also provided in the device to interface with speakers/microphone 522 thereby providing sounds and/or music.

The general-purpose storage controller 524 connects the storage medium disk 504 with communication bus 526, which may be an ISA, EISA, VESA, PCI, or similar, for interconnecting the components of the device. A description of the general features and functionality of the display 510, keyboard and/or mouse 514, as well as the display controller 608, storage controller 524, network controller 506, sound controller 520, and general purpose I/O interface 512 is omitted herein for brevity as these features are known.

Numerous modifications and variations are possible in light of the above teachings. It is therefore to be understood that within the scope of the appended claims, the embodiments may be practiced otherwise than as specifically described herein.

Aspects of the disclosure provide a multi-layer printed circuit board (PCB). The PCB includes a core layer, a first stack of alternative layers including metal layers and dielectric layers stacked alternatively over a top surface of the core layer, a second stack of alternative layers including metal layers and dielectric layers stacked alternatively over a bottom surface of the core layer, and an embedded via structure through the core layer and connecting a first metal layer of the first stack of alternative layers to a second metal layer of the second stack of alternative layers. The embedded via structure includes a first signal path layer through the core layer, a first ground layer through the core layer and enclosing the first signal path layer, and a first dielectric layer through the core layer and between the first signal path layer and the first ground layer.

In an embodiment, the embedded via structure further includes a second dielectric layer that is enclosed by the first signal path layer.

In an embodiment, the embedded via structure further includes a second signal path layer that is enclosed by the first ground layer.

In an embodiment, the first and second signal path layers are not enclosed by each other.

In an embodiment, one of the first and second signal path layers is enclosed by the other of the first and second signal path layers.

In an embodiment, the embedded via structure further includes a third dielectric layer that is enclosed by the second signal path layer.

In an embodiment, the embedded via structure further includes a second ground layer enclosed by the first signal path layer.

In an embodiment, the embedded via structure further includes a fourth dielectric layer enclosed by the second ground layer.

In an embodiment, the core layer and the dielectric layers include a prepreg dielectric material.

In an embodiment, the core layer has a cavity.

Aspects of the disclosure further provide a method of manufacturing a PCB. The method includes, forming a first stack of alternative layers including metal layers and dielectric layers stacked alternatively over a top surface of a core layer of the PCB, forming a second stack of alternative layers including metal layers and dielectric layers stacked alternatively over a bottom surface of the core layer, and forming an embedded via structure through the core layer and connecting a first metal layer of the first stack of alternative layers to a second metal layer of the second stack of alternative layers. The embedded via structure includes a first signal path layer through the core layer, a first ground layer through the core layer and enclosing the first signal path layer, and a first dielectric layer through the core layer and between the first signal path layer and the first ground layer.

In an embodiment, the embedded via structure further includes a second dielectric layer that is enclosed by the first signal path layer.

In an embodiment, the embedded via structure further includes a second signal path layer that is enclosed by the first ground layer.

In an embodiment, the first and second signal path layers are not enclosed by each other.

In an embodiment, one of the first and second signal path layers is enclosed by the other of the first and second signal path layers.

In an embodiment, the embedded via structure further includes a third dielectric layer that is enclosed by the second signal path layer.

In an embodiment, the embedded via structure further includes a second ground layer enclosed by the first signal path layer.

In an embodiment, the embedded via structure further includes a fourth dielectric layer enclosed by the second ground layer.

In an embodiment, the core layer and the dielectric layers include a prepreg dielectric material.

In an embodiment, the core layer has a cavity.

Aspects of the disclosure further provide a non-transitory computer-readable storage medium including computer executable instructions, wherein the instructions, when executed by a computer, cause the computer to perform a method, the method comprising: forming a first stack of alternative layers including metal layers and dielectric layers that are stacked alternatively over a top surface of a core layer of the PCB; forming a second stack of alternative layers including metal layers and dielectric layers that are stacked alternatively over a bottom surface of the core layer; and forming an embedded via structure that is through the core layer and connects a first metal layer of the first stack of alternative layers to a second metal layer of the second stack of alternative layers, the embedded via structure including a first signal path layer that is through the core layer, a first ground layer that is through the core layer and encloses the first signal path layer, and a first dielectric layer that is through the core layer and between the first signal path layer and the first ground layer.

While aspects of the present disclosure have been described in conjunction with the specific embodiments thereof that are proposed as examples, alternatives, modifications, and variations to the examples may be made. Accordingly, embodiments as set forth herein are intended to be illustrative and not limiting. There are changes that may be made without departing from the scope of the claims set forth below.

What is claimed is:

1. A multi-layer printed circuit board (PCB), comprising:
a core layer;
a first stack of alternative layers including metal layers and dielectric layers that are stacked alternatively over a top surface of the core layer;
a second stack of alternative layers including metal layers and dielectric layers that are stacked alternatively over a bottom surface of the core layer; and
an embedded via structure that is through the core layer and connects a first metal layer of the first stack of alternative layers to a second metal layer of the second stack of alternative layers, the embedded via structure including a first signal path layer that is through the core layer, a first ground layer that is through the core layer and encloses the first signal path layer, and a first dielectric layer that is through the core layer and between the first signal path layer and the first ground layer.

2. The multi-layer PCB of claim 1, wherein the embedded via structure further includes a second dielectric layer that is enclosed by the first signal path layer.

3. The multi-layer PCB of claim 1, wherein the embedded via structure further includes a second signal path layer that is enclosed by the first ground layer.

4. The multi-layer PCB of claim 3, wherein the first and second signal path layers are not enclosed by each other.

5. The multi-layer PCB of claim 3, wherein one of the first and second signal path layers is enclosed by the other of the first and second signal path layers.

6. The multi-layer PCB of claim 3, wherein the embedded via structure further includes a third dielectric layer that is enclosed by the second signal path layer.

7. The multi-layer PCB of claim 1, wherein the embedded via structure further includes a second ground layer enclosed by the first signal path layer.

8. The multi-layer PCB of claim 7, wherein the embedded via structure further includes a fourth dielectric layer enclosed by the second ground layer.

9. The multi-layer PCB of claim 1, wherein the core layer and the dielectric layers include a prepreg dielectric material.

10. The multi-layer PCB of claim 1, wherein the core layer has a cavity.

11. A method of manufacturing a multi-layer printed circuit board (PCB), the method comprising:
forming a first stack of alternative layers including metal layers and dielectric layers that are stacked alternatively over a top surface of a core layer of the PCB;
forming a second stack of alternative layers including metal layers and dielectric layers that are stacked alternatively over a bottom surface of the core layer; and
forming an embedded via structure that is through the core layer and connects a first metal layer of the first stack of alternative layers to a second metal layer of the second stack of alternative layers, the embedded via structure including a first signal path layer that is through the core layer, a first ground layer that is through the core layer and encloses the first signal path layer, and a first dielectric layer that is through the core layer and between the first signal path layer and the first ground layer.

12. The method of claim 11, wherein the embedded via structure further includes a second dielectric layer that is enclosed by the first signal path layer.

13. The method of claim 11, wherein the embedded via structure further includes a second signal path layer that is enclosed by the first ground layer.

14. The method of claim 13, wherein the first and second signal path layers are not enclosed by each other.

15. The method of claim 13, wherein one of the first and second signal path layers is enclosed by the other of the first and second signal path layers.

16. The method of claim 13, wherein the embedded via structure further includes a third dielectric layer that is enclosed by the second signal path layer.

17. The method of claim 11, wherein the embedded via structure further includes a second ground layer enclosed by the first signal path layer.

18. The method of claim 17, wherein the embedded via structure further includes a fourth dielectric layer enclosed by the second ground layer.

19. The method of claim 11, wherein the core layer and the dielectric layers include a prepreg dielectric material.

20. A non-transitory computer-readable storage medium including computer executable instructions, wherein the instructions, when executed by a computer, cause the computer to perform a method, the method comprising:
forming a first stack of alternative layers including metal layers and dielectric layers that are stacked alternatively over a top surface of a core layer of a multi-layer printed circuit board (PCB),;
forming a second stack of alternative layers including metal layers and dielectric layers that are stacked alternatively over a bottom surface of the core layer; and
forming an embedded via structure that is through the core layer and connects a first metal layer of the first stack of alternative layers to a second metal layer of the second stack of alternative layers, the embedded via structure including a first signal path layer that is through the core layer, a first ground layer that is through the core layer and encloses the first signal path layer, and a first dielectric layer that is through the core layer and between the first signal path layer and the first ground layer.
